(19) United States
(12) Patent Application Publication
(10) Pub. No.: US 2021/0035918 A1
(43) Pub. Date: Feb. 4, 2021

(54) SEMICONDUCTOR STRUCTURE AND FABRICATION METHOD THEREOF

(71) Applicant: NANYA TECHNOLOGY CORPORATION, New Taipei cit;y (TW)

(72) Inventors: Ting-Cih KANG, New Taipei City (TW); Hsih-Yang CHIU, Taoyuan City (TW)

(21) Appl. No.: 16/527,046

(22) Filed: Jul. 31, 2019

(51) Int. Cl. H01L 23/552; H01L 23/48; H01L 23/528; H01L 21/768

(52) U.S. Cl. CPC H01L 23/552; H01L 21/76898; H01L 23/528; H01L 23/481

(57) ABSTRACT

A semiconductor structure includes a semiconductor substrate, a shielding structure, a ground terminal, and a through silicon via. The shielding structure is disposed over the semiconductor substrate and includes a first metal layer, a second metal layer, and a third metal layer. The first metal layer is disposed over the semiconductor substrate. The second metal layer is disposed over the first metal layer. The third metal layer is disposed over the second metal layer. The ground terminal is electrically connected to the third metal layer. The through silicon via is disposed over the semiconductor substrate and adjacent to the shielding structure.

### BACKGROUND

### Technical Field

The present disclosure relates to a semiconductor structure and a fabrication method of the semiconductor structure.

### Description of Related Art

With the rapid growth of electronic industry, the development of integrated circuits (ICs) has achieved high performance and miniaturization. Technological advances in IC materials and design have produced generations of ICs where each generation has smaller and more complex circuits than the previous generation.

As the number of electronic devices on single chips rapidly increases, three-dimensional (3D) integrated circuit layouts, or stacked chip designs, have been utilized for certain semiconductor devices in an effort to overcome the feature size and density limitations associated with 2D layouts. Generally, in a 3D IC design, two or more semiconductor dies are bonded together, and electrical connections are formed between each die. One method of facilitating the chip-to-chip electrical connections is by using through-silicon vias (TSVs). A TSV is a vertical electrical connection that passes through a silicon wafer or die, allowing for more simplified interconnection of vertically aligned electronic devices, thereby significantly reducing integrated circuit layout complexity as well as overall dimensions of a multi-chip circuit. Some of the benefits associated with the interconnect technology enabled by 3D integrated circuit designs include accelerated data exchange, reduced power consumption, and much higher input/output voltage densities. However, parasitic components between wires and through silicon vias result in signal coupling in three dimension (3D) IC, thereby generating noisy and affecting performance of the semiconductor device.

### SUMMARY

According to some embodiments of the present disclosure, a semiconductor structure includes a semiconductor substrate, a shielding structure, a ground terminal, and a through silicon via. The shielding structure is disposed over the semiconductor substrate and includes a first metal layer, a second metal layer, and a third metal layer. The first metal layer is disposed over the semiconductor substrate. The second metal layer is disposed over the first metal layer. The third metal layer is disposed over the second metal layer. The ground terminal is electrically connected to the third metal layer. The through silicon via is disposed over the semiconductor substrate and adjacent to the shielding structure.

According to some embodiments of the present disclosure, the through silicon via is surrounded by the shielding structure.

According to some embodiments of the present disclosure, the first metal layer and the second metal layer overlap with each other.

According to some embodiments of the present disclosure, the shielding structure has a first portion and a second portion opposite the first portion. The through silicon via is between the first portion and the second portion of the shielding structure.

According to some embodiments of the present disclosure, a first line is between a center of the through silicon via and an end of the first portion. A second line is between the center of the through silicon via and another end of the first portion. A first angle is formed between the first line the second line. A third line is between the center of the through silicon via and an end of the second portion. A fourth line is between the center of the through silicon via and another end of the second portion. A second angle is formed between the third line and the fourth line.

According to some embodiments of the present disclosure, a sum of the first angle and the second angle divided by 360° is in a range from 50% to 100%.

According to some embodiments of the present disclosure, the shielding structure further has a third portion adjoining the first portion and the second portion, such that the shielding structure is U-shaped when viewed from above. The through silicon via is among the first portion, the second portion, and the third portion.

According to some embodiments of the present disclosure, a third angle is formed between the first line and the third line. A sum of the first angle, the second angle, and the third angle divided by 360° is in a range from 50% to 100%.

According to some embodiments of the present disclosure, a gap between the shielding structure and the through silicon via is greater than a radius of the through silicon via and smaller than twice the radius of the through silicon via.

According to some embodiments of the present disclosure, the semiconductor structure further includes a first dielectric layer and a conductor. The first dielectric layer is disposed between the semiconductor substrate and the first metal layer. The conductor is disposed in the first dielectric layer and on the semiconductor substrate.

According to some embodiments of the present disclosure, the semiconductor structure further includes a second dielectric layer between the first metal layer and the second metal layer. The second metal layer has a vertical portion in the second dielectric layer and on the first metal layer.

According to some embodiments of the present disclosure, the semiconductor structure further includes a third dielectric layer between the second metal layer and the third metal layer. The third metal layer has a vertical portion in the third dielectric layer and on the second metal layer.

According to some embodiments of the present disclosure, a top surface of the through silicon via is at same horizontal level as a bottom surface of the third metal layer.

According to some embodiments of the present disclosure, a material of the through silicon via is the same as that of the first metal layer and the second metal layer, but is different from that of the third metal layer.

According to some embodiments of the present disclosure, the semiconductor substrate is a p-type semiconductor substrate.

According to some embodiments of the present disclosure, a fabrication method of a semiconductor structure includes following steps. A first metal layer is formed over a semiconductor substrate. A second metal layer is formed over the first metal layer. A through silicon via is formed adjacent to the first metal layer and the second metal layer. A third metal layer is formed over the second metal layer. The third metal layer is electrically connected to a ground terminal.

According to some embodiments of the present disclosure, the fabrication method of the semiconductor structure further includes forming a first dielectric layer over the semiconductor substrate before the first metal layer is formed.

According to some embodiments of the present disclosure, the method further includes forming a second dielectric layer over the first metal layer before the second metal layer is formed.

According to some embodiments of the present disclosure, the fabrication method of the semiconductor structure further includes forming a third dielectric layer over the second metal layer before the third metal layer is formed.

According to some embodiments of the present disclosure, forming the through silicon via is such that the through silicon via is surrounded by the first metal layer, the second metal layer, and the third metal layer.

In summary, the disclosure provides the semiconductor structure and the fabrication method of the semiconductor structure. Since the ground terminal is electrically connected to the third metal layer of the shielding structure and the through silicon via is adjacent to the shielding structure, noise associated with the through silicon via can be decreased and the performance of the semiconductor structure can be improved.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a top view of a semiconductor structure in accordance with some embodiments of the present disclosure;

FIG. 2 is a cross-sectional view of the semiconductor structure taken along line 2-2 of FIG. 1;

FIGS. 3-10 are cross-sectional views of a fabrication method of the semiconductor structure at various stages in accordance with some embodiments of the present disclosure;

FIG. 11 is a top view of a semiconductor structure in accordance with an embodiment of the present disclosure;

FIG. 12 is a top view of a semiconductor structure in accordance with an embodiment of the present disclosure; and

FIG. 13 is a top view of a semiconductor structure in accordance with an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

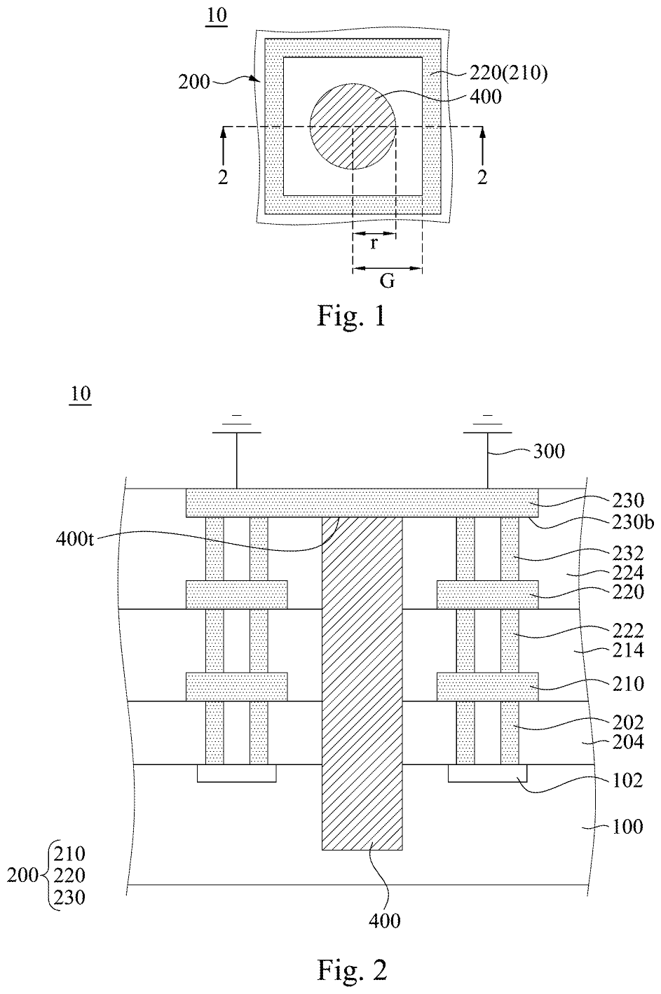

Referring to FIG. 1 and FIG. 2, FIG. 1 is a top view of a semiconductor structure 10 in accordance with some embodiments of the present disclosure, and FIG. 2 is a cross-sectional view of the semiconductor structure 10 taken along line 2-2 of FIG. 1. For clarity, a third metal layer 230 and a third dielectric layer 224 of FIG. 2 are not shown in FIG. 1. The semiconductor structure 10 includes a semiconductor substrate 100, a shielding structure 200, a ground terminal 300, and a through silicon via (TSV) 400.

In some embodiments, the semiconductor substrate 100 may be a silicon substrate. Alternatively, the semiconductor substrate 100 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In addition, the semiconductor substrate 100 may be a p-type substrate, such as a silicon material doped with a p-type dopant (e.g., boron). In some embodiments, the semiconductor substrate 100 further includes a pad 102.

The shielding structure 200 is disposed over the semiconductor substrate 100 and includes a first metal layer 210, a second metal layer 220, and a third metal layer 230. The first metal layer 210 is disposed over the semiconductor substrate 100. The second metal layer 220 is disposed over the first metal layer 210. The third metal layer 230 is disposed over the second metal layer 220.

In some embodiments, the first metal layer 210 and the second metal layer 220 overlap with each other. In other words, a vertical projection region of the second metal layer 220 on the semiconductor substrate 100 overlaps with a vertical projection region of the first metal layer 210 on the semiconductor substrate 100. In some embodiments, the first metal layer 210, the second metal layer 220, and the third metal layer 230 overlap with each other.

In some embodiments, the first metal layer 210 and the second metal layer 220 may be made of conductive materials, such as copper or other suitable conductive materials. In some embodiments, the material of the first metal layer 210 is the same as the material of the second metal layer 220.

Moreover, the third metal layer 230 may be made of conductive materials, such as aluminum or other suitable conductive materials. In some embodiments, the material of the third metal layer 230 is different from the materials of the first metal layer 210 and the second metal layer 220.

The ground terminal 300 is electrically connected to the third metal layer 230 of the shielding structure 200. Because the ground terminal 300 is electrically connected to the third metal layer 230, an induced current may not be generated. The through silicon via 400 is disposed over the semiconductor substrate 100 and adjacent to the shielding structure 200. That is, the through silicon via 400 is disposed adjacent to the first metal layer 210, the second metal layer 220, and the third metal layer 230. Since the ground terminal 300 is electrically connected to the third metal layer 230 of the shielding structure 200 and the through silicon via 400 is adjacent to the shielding structure 200, noise associated with the through silicon via 400 can be decreased and the performance of the semiconductor structure 10 can be improved.

In some embodiments, the through silicon via 400 is surrounded by the shielding structure 200. In greater details, the through silicon via 400 is surrounded by the first metal layer 210, the second metal layer 220, and the third metal layer 230. Since through silicon via 400 is surrounded by the shield structure 200, the shielding effect can be improved.

In some embodiments, a top surface 400t of the through silicon via 400 is at same horizontal level as a bottom surface 230b of the third metal layer 230. In some embodiments, the third metal layer 230 covers the through silicon via 400.

In some embodiments, a gap G is between the shielding structure 200 and the through silicon via 400. The gap G is greater than a radius r of the through silicon via 400 and smaller than twice the radius r of the through silicon via 400, such that the through silicon via 400 is spaced apart from the shielding structure 200.

In some embodiments, the through silicon via 400 may be made of conductive materials, such as copper or other suitable conductive materials. In some embodiments, the material of the through silicon via 400 is the same as the materials of the second metal layer 220 and the first metal layer 210, but is different from the material of the third metal layer 230.

Furthermore, the semiconductor structure 10 further includes a first dielectric layer 204 and a conductor 202. The first dielectric layer 204 is disposed between the semiconductor substrate 100 and the first metal layer 210. The conductor 202 is disposed in the first dielectric layer 204 and on the semiconductor substrate 100. In other words, the conductor 202 is disposed between the pad 102 of the semiconductor substrate 100 and the first metal layer 210.

In some embodiments, the semiconductor structure 10 further includes a second dielectric layer 214 between the first metal layer 210 and the second metal layer 220. The second metal layer 220 has a vertical portion 222 in the second dielectric layer 214 and on the first metal layer 210. In other words, the vertical portion 222 is disposed between the first metal layer 210 and the second metal layer 220.

In some embodiments, the semiconductor structure 10 further includes a third dielectric layer 224 between the second metal layer 220 and the third metal layer 230. The third metal layer 230 has a vertical portion 232 in the third dielectric layer 224 and on the second metal layer 220. In other words, the vertical portion 232 is disposed between the second metal layer 220 and the third metal layer 230.

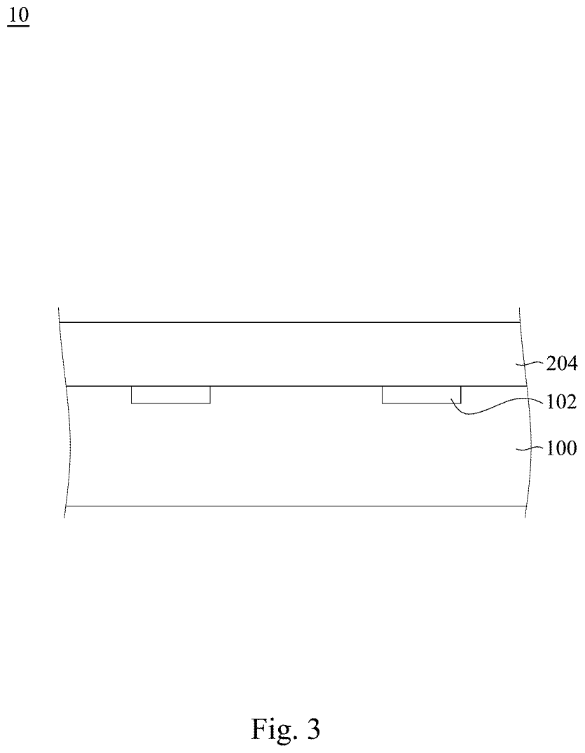

FIGS. 3-10 are cross-sectional views of a fabrication method of the semiconductor structure 10 at various stages in accordance with some embodiments of the present disclosure.

Referring to FIG. 3, the first dielectric layer 204 is formed on the semiconductor substrate 100. The method of forming the first dielectric layer 204 may include, for example, PVD, CVD, ALD, or other suitable technique. In some embodiments, the first dielectric layer 204 may include a single or multiple layers. The first dielectric layer 204 may include silicon oxide, silicon nitride, silicon oxynitride, or other suitable materials.

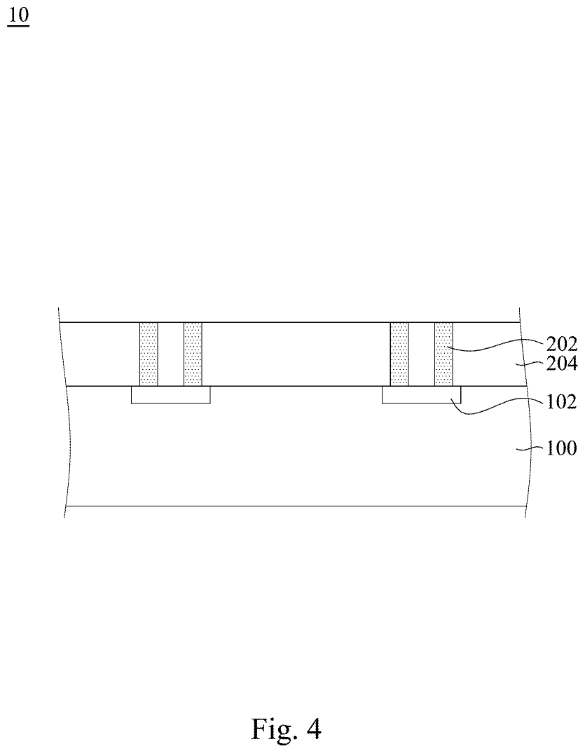

Referring to FIG. 4, the conductor 202 is formed in the first dielectric layer 204 and on the semiconductor substrate 100. Example, an etching process may be performed to form a via hole in the first dielectric layer 204, and then a conductive material may be filled in the via hole to form the conductor 202.

In some embodiments, the conductor 202 may be made of conductive materials, such as tungsten or other suitable conductive materials.

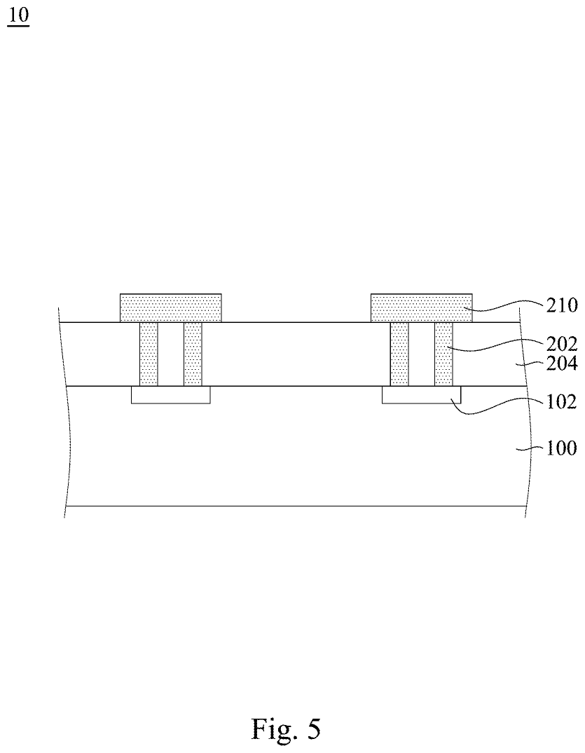

Referring to FIG. 5, the first metal layer 210 is formed over the first dielectric layer 204 and the conductor 202. In some embodiments, the first metal layer 210 is in contact with the conductor 202. The method of forming the first metal layer 210 may include forming a metal material layer and then patterning the metal material layer with a photolithography process.

In some embodiments, the conductor 202 is between the semiconductor substrate 100 and the first metal layer 210. In some embodiments, the material of the first metal layer 210 is different from the material of the conductor 202. For example, the material of the first metal layer 210 is copper, while the material of the conductor 202 is tungsten.

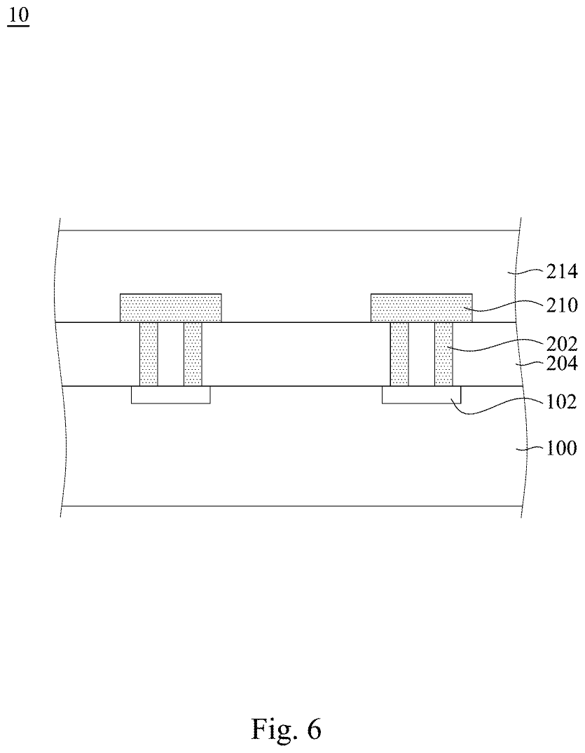

Referring to FIG. 6, the second dielectric layer 214 is formed over the first metal layer 210 and the first dielectric layer 204. The method of forming the second dielectric layer 214 may include, for example, PVD, CVD, ALD, or other suitable technique. In some embodiments, the second dielectric layer 214 may include a single or multiple layers. The second dielectric layer 214 may include silicon oxide, silicon nitride, silicon oxynitride, or other suitable materials.

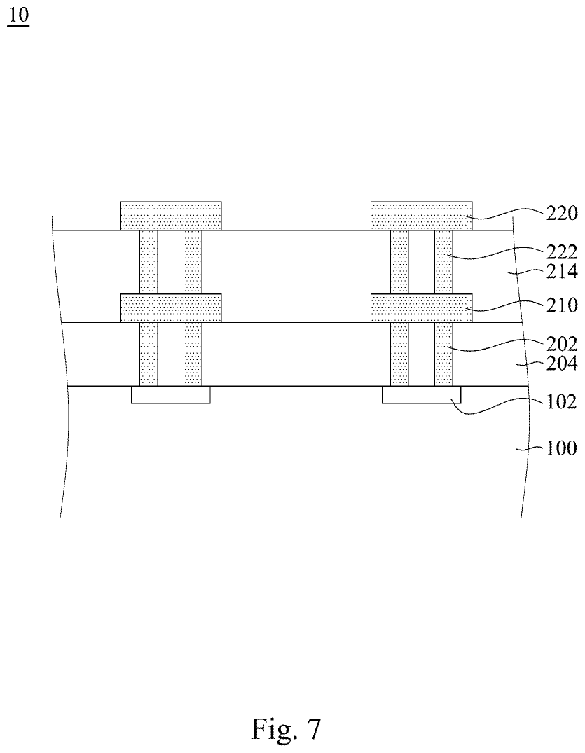

Referring to FIG. 7, the second metal layer 220 is formed over the first metal layer 210 and the second dielectric layer 214. The method of forming the second metal layer 220 may include forming a metal material layer and then patterning the metal material layer with a photolithography process. In some embodiments, the second metal layer 220 further includes the vertical portion 222 in the second dielectric layer 214 and on the first metal layer 210. In some embodiments, the vertical portion 222 of the second metal layer 220 is substantially aligned with the conductor 202. In other words, a vertical projection region of the vertical portion 222 of the second metal layer 220 on the semiconductor substrate 100 overlaps with a vertical projection region of the conductor 202.

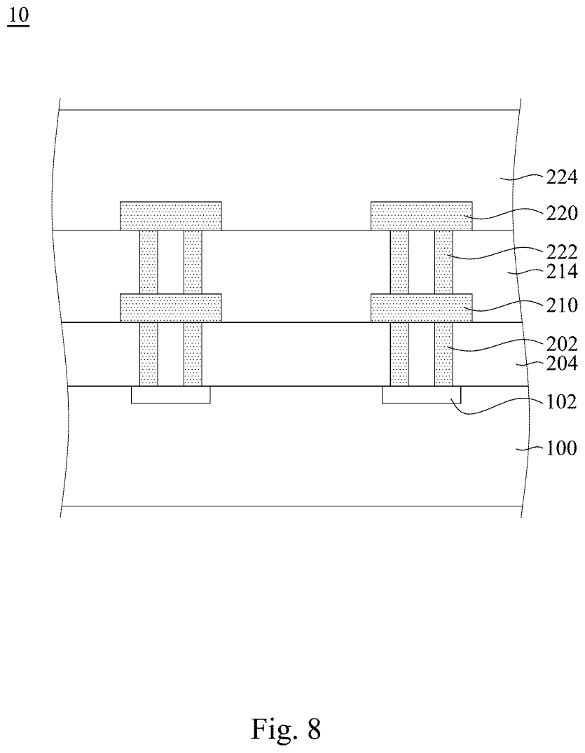

Referring to FIG. 8, the third dielectric layer 224 is formed over the second metal layer 220 and the second dielectric layer 214. The method of forming the third dielectric layer 224 may include, for example, PVD, CVD, ALD, or other suitable technique. In some embodiments, the third dielectric layer 224 may include a single or multiple layers. The third dielectric layer 224 may include silicon oxide, silicon nitride, silicon oxynitride, or other suitable materials.

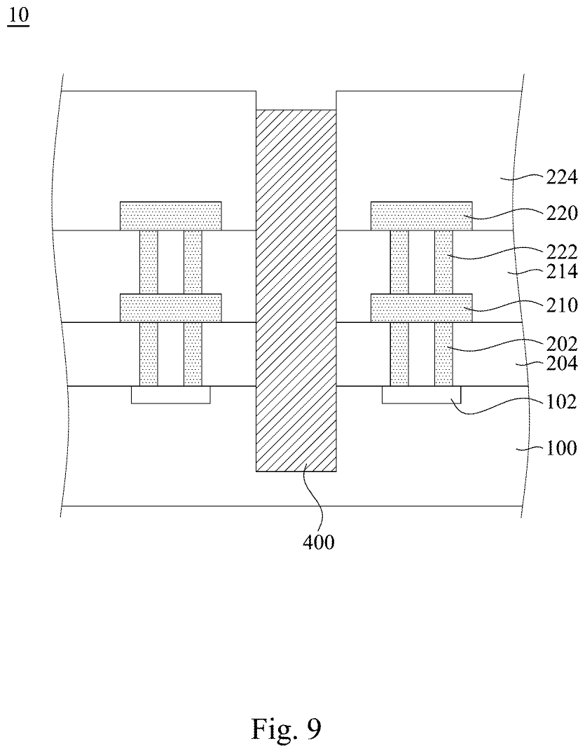

Referring to FIG. 9, the through silicon via 400 is formed adjacent to the first metal layer 210 and the second metal layer 220. Specifically, the through silicon via 400 is through the first dielectric layer 204, the second dielectric layer 214, the third dielectric layer 224, and a portion of the semiconductor substrate 100.

In some embodiments, an etching process may be performed to form a via hole penetrating the first dielectric layer 204, the second dielectric layer 214, the third dielectric layer 224, and the portion of the semiconductor substrate 100, and then a conductive material may be filled in the via hole to form the through silicon via 400.

In some embodiments, a vertical projection region of the through silicon via 400 on the semiconductor substrate 100 does not overlap with the vertical projection regions of the first metal layer 210 and the second metal layer 220 on the semiconductor substrate 100. Stated differently, the vertical projection region of the through silicon via 400 on the semiconductor substrate 100 is spaced apart from each of the vertical projection regions of the first metal layer 210 and the second metal layer 220 on the semiconductor substrate 100.

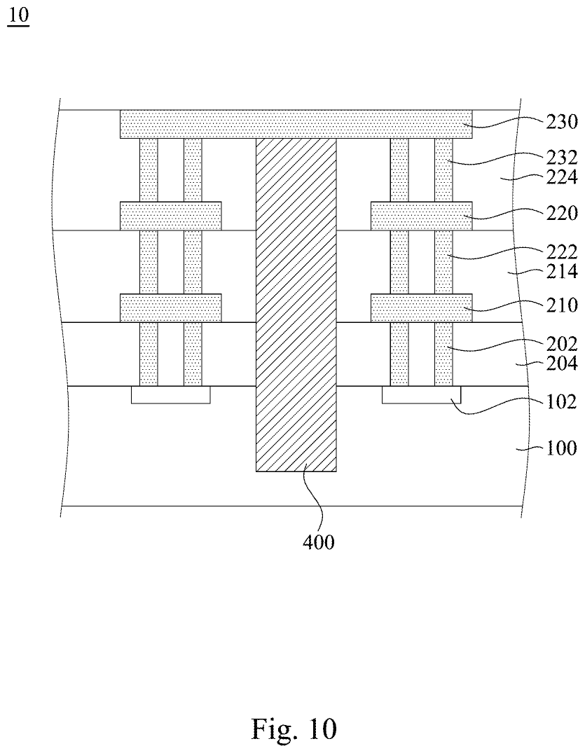

Referring to FIG. 10, the third metal layer 230 is formed over the second metal layer 220 and the third dielectric layer 224. In greater details, the third dielectric layer 224 is patterned before the third metal layer is formed. In some embodiments, the third metal layer 230 further includes the vertical portion 232 in the third dielectric layer 224 and on the second metal layer 220. In some embodiments, the vertical portion 232 of the third metal layer 230 is substantially aligned with the vertical portion 222 of the second metal layer 220. In other words, a vertical projection region of the vertical portion 232 of the third metal layer 230 on the semiconductor substrate 100 overlaps with the vertical projection region of the vertical portion 222 of the second metal layer 220.

In some embodiments, the third metal layer 230 covers the through silicon via 400, and through silicon via 400 is formed such that the through silicon via 400 is surrounded by the first metal layer 210, the second metal layer 220, and the third metal layer 230.

After the third metal layer 230 is formed, the third metal layer 230 is electrically connected to the ground terminal 300, as shown in FIG. 2.

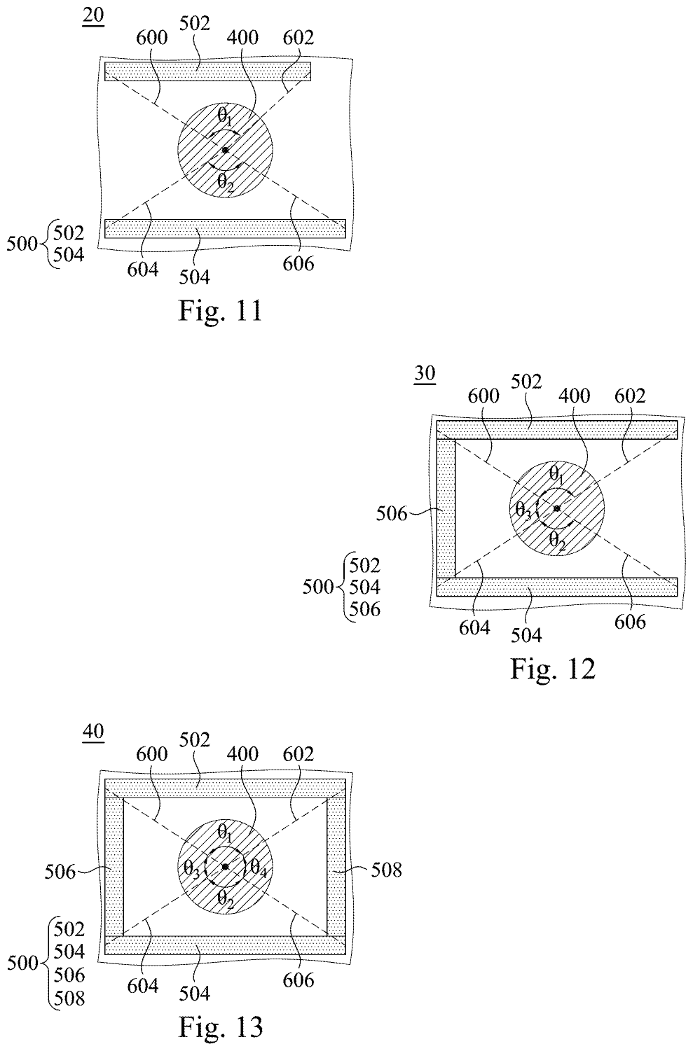

Referring to FIG. 11, FIG. 11 is a top view of a semiconductor structure 20 in accordance with an embodiment of the present disclosure. The semiconductor structure 20 includes a shielding structure 500 and the through silicon via 400. The difference between this embodiment and the embodiment of FIG. 2 is that the shielding structure 500 has a first portion 502 and a second portion 504 opposite the first portion 502 and does not have the other two opposite portions of FIG. 2. The through silicon via 400 is disposed between the first portion 502 and the second portion 504 of the shielding structure 500. A first line 600 is between a center of the through silicon via 400 and an end of the first portion 502. A second line 602 is between the center of the through silicon via 400 and another end of the first portion 502. A first angle θ₁ is between the first line 600 and the second line 602. A third line 604 is between the center of the through silicon via 400 and an end of the second portion 504. A fourth line 606 is between the center of the through silicon via 400 and another end of the second portion 504. A second angle θ₂ is formed between the third line 604 and the fourth line 606. In some embodiments, a sum of the first angle θ₁ and the second angle θ₂ divided by 360° is in a range from 50% to 100%. The sum of the first angle θ₁ and the second angle θ₂ divided by 360° are served as a wire coverage ratio, and the larger wire coverage ratio results in stronger electric field (E-field) sharing and smaller capacitance per unit length. In other words, the shielding structure 500 is beneficial to shield coupling between the through silicon via 400 and the wire outside the semiconductor structure 20, and thus the signal-to-noise (SNR) value can be improved. In some embodiments, the sum of the first angle θ₁ and the second angle θ₂ divided by 360° is about 50%.

Referring to FIG. 12, FIG. 12 is top view of a semiconductor structure 30 in accordance with an embodiment of the present disclosure. The difference between this embodiment and the embodiment of FIG. 11 is that the shielding structure 500 further has a third portion 506 adjoining the first portion 502 and the second portion 504, such that the shielding structure 500 is U-shaped when viewed from above. The through silicon via 400 is among the first portion 502, the second portion 504, and the third portion 506. A third angle θ₃ is formed between the first line 600 and the third line 604. A sum of the first angle θ₁, the second angle θ₂, and the third angle θ₃ divided by 360° is in a range from 50% to 100%. In some embodiments, the sum of the first angle θ₁, the second angle θ₂, and the third angle θ₃ divided by 360° is about 75%.

Referring to FIG. 13, FIG. 13 is top view of a semiconductor structure 40 in accordance with an embodiment of the present disclosure. The difference between this embodiment and the embodiment of FIG. 11 is that the shielding structure 500 further has a fourth portion 508 adjoining the first portion 502 and the second portion 504. The fourth portion 508 is opposite the third portion 506. The through silicon via 400 is among the first portion 502, the second portion 504, the third portion 506, and the fourth portion 508. In other words, the through silicon via 400 is surrounded by the shielding structure 500. A third angle θ₄ is formed between the second line 602 and the fourth line 606. A sum of the first angle θ₁, the second angle θ₂, the third angle θ₃, and the fourth angle θ₄ divided by 360° is 100%, in the present embodiment.

In summary, the disclosure provides the semiconductor structure and the fabrication method of the semiconductor structure. Because the ground terminal is electrically connected to the third metal layer of the shielding structure and the through silicon via is disposed over the semiconductor substrate and adjacent to the shielding structure, noise associated with the through silicon via can be decreased and the performance of the semiconductor structure can be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor structure, comprising:
a semiconductor substrate;
a shielding structure over the semiconductor substrate and comprising:
a first metal layer over the semiconductor substrate;
a second metal layer over the first metal layer;
a third metal layer over the second metal layer;
a ground terminal electrically connected to the third metal layer; and
a through silicon via over the semiconductor substrate and adjacent to the shielding structure.

2. The semiconductor structure of claim 1, wherein the through silicon via is surrounded by the shielding structure.

3. The semiconductor structure of claim 1, wherein the first metal layer and the second metal layer overlap with each other.

4. The semiconductor structure of claim 1, wherein the shielding structure has a first portion and a second portion opposite the first portion, and the through silicon via is between the first portion and the second portion of the shielding structure.

5. The semiconductor structure of claim 4, wherein a first line is between a center of the through silicon via and an end of the first portion, a second line is between the center of the through silicon via and another end of the first portion, and a first angle is formed between the first line and the second line; and
wherein a third line is between the center of the through silicon via and an end of the second portion, a fourth line is between the center of the through silicon via and another end of the second portion, and a second angle is formed between the third line and the fourth line.

6. The semiconductor structure of claim 5, wherein a sum of the first angle and the second angle divided by 360° is in a range from 50% to 100%.

7. The semiconductor structure of claim 4, wherein the shielding structure further has a third portion adjoining the first portion and the second portion, such that the shielding structure is U-shaped when viewed from above, and the through silicon via is among the first portion, the second portion, and the third portion.

8. The semiconductor structure of claim 5, wherein a third angle is formed between the first line and the third line, and a sum of the first angle, the second angle, and the third angle divided by 360° is in a range from 50% to 100%.

9. The semiconductor structure of claim 1, wherein a gap between the shielding structure and the through silicon via is greater than a radius of the through silicon via and smaller than twice the radius of the through silicon via.

10. The semiconductor structure of claim 1, further comprising:
a first dielectric layer between the semiconductor substrate and the first metal layer; and
a conductor in the first dielectric layer and on the semiconductor substrate.

11. The semiconductor structure of claim 10, further comprising:
a second dielectric layer between the first metal layer and the second metal layer, wherein the second metal layer has a vertical portion in the second dielectric layer and on the first metal layer.

12. The semiconductor structure of claim 11, further comprising:
a third dielectric layer between the second metal layer and the third metal layer, wherein the third metal layer has a vertical portion in the third dielectric layer and on the second metal layer.

13. The semiconductor structure of claim 1, wherein a top surface of the through silicon via is at same horizontal level as a bottom surface of the third metal layer.

14. The semiconductor structure of claim 1, wherein a material of the through silicon via is the same as that of the first metal layer and the second metal layer, but is different from that of the third metal layer.

15. The semiconductor structure of claim 1, wherein the semiconductor substrate is a p-type semiconductor substrate.

16. A fabrication method of a semiconductor structure, comprising:
forming a first metal layer over a semiconductor substrate;
forming a second metal layer over the first metal layer;
forming a through silicon via adjacent to the first metal layer and the second metal layer;
forming a third metal layer over the second metal layer; and
electrically connecting the third metal layer to a ground terminal.

17. The fabrication method of the semiconductor structure of claim 16, further comprising:
forming a first dielectric layer over the semiconductor substrate before the first metal layer is formed.

18. The fabrication method of the semiconductor structure of claim 17, further comprising:
forming a second dielectric layer over the first metal layer before the second metal layer is formed.

19. The fabrication method of the semiconductor structure of claim 18, further comprising:
forming a third dielectric layer over the second metal layer before the third metal layer is formed.

20. The fabrication method of the semiconductor structure of claim 16, wherein forming the through silicon via is such that the through silicon via is surrounded by the first metal layer, the second metal layer, and the third metal layer.
